(19) United States
(12) Patent Application Publication
(10) Pub. No.: US 2003/0141868 A1
(43) Pub. Date: Jul. 31, 2003

(54) High balance gradiometer

(76) Inventor: Alexander A. Bakharev, Niskayuna, NY (US)

Correspondence Address: KATTEN MUCHIN ZAVIS ROSENMAN, 575 MADISON AVENUE, NEW YORK, NY, 10022-2585, US

(21) Appl. No.: 10/375,939

(22) Filed: Feb. 25, 2003

Related U.S. Application Data
(63) Continuation of application No. PCT/US01/26306, filed on Aug. 23, 2001.

(51) Int. Cl. G01R 33/02; G01R 33/035

(52) U.S. Cl. 324/248; 327/527

(57) ABSTRACT

High balance, in the range of about 4×10⁻⁴ to about 10⁻³, is achieved in a gradiometer using Pyrex as the gradiometer support material. A superior technique is disclosed for winding superconducting wire loops with equal loop areas wherein cyanoacrylate glue is used to reduce slack in the wire in the process of winding. Furthermore, a minimal number of turns for each gradiometer type are used to maintain gradiometer sensitivity and to maintain high degree of mechanical balance. Additionally, low sensitivity SQUID magnetometers with optimally selected loop areas are placed among gradiometer channels in the directions of x, y, and z to measure magnetic fields. These measured fields are then fed into the gradiometer with coefficients roughly equal to (−1) (inversion) to compensate for the imbalances in the x, y, and z direction.

### BACKGROUND OF THE INVENTION

1. Field of Invention

The present invention relates generally to the field of magnetic field measurement. More specifically, the present invention is related to measuring small magnetic fields with Superconducting Quantum Interference Devices (SQUIDs) equipped with highly balanced gradiometers, and to ways of further improving the balance via electronic means.

2. Discussion of Prior Art

Superconducting Quantum Interference Devices (SQUIDs) are magnetic sensors used in sensitive magnetometers that are used for measuring magnetic fields below approximately 10⁻¹⁰ Tesla (T). This is the range of magnetic fields produced by living organisms (also called biomagnetic fields). For example, a human heart produces fields between 10⁻¹² T and 10⁻¹⁰ T just outside of a chest surface. The magnetic fields emanated from the human brain just outside of a head are of the order of 10⁻¹⁴ T-10⁻¹² T. These numbers can be compared with the earth's magnetic field of about 10⁻⁴ T and typical urban magnetic noise of 10⁻⁸ T-10⁻⁶ T.

To be more precise, SQUIDs react to a magnetic flux rather than a field. Magnetic flux, Φ_{B}, is defined as a product of the projection of the magnetic field threading a given area along the area's normal z, times that area A, or

Φ_{B}=B_{z}A

A low-Tc dc-SQUID is an ultra-sensitive, low-noise transducer of magnetic flux Φ_{B} to voltage, consisting of two nominally identical superconducting elements called Josephson junctions serially connected in a superconducting loop. The SQUID loop is typically quite small, typically 10⁻⁴-10⁻² mm². Today, SQUIDs are produced on a chip, using Nb—Al junction technology, wherein the junctions and the SQUID loop are made of thin films. The micron-scale dimensions of the layout are defined using photolithographic techniques. The SQUID is typically enclosed in a superconducting shield that helps screen the device from ambient magnetic flux. The magnetic flux to be measured is intercepted by considerably larger, typically (10-20) mm diameter loops or coils (called pick-up or detection coils) inductively coupled to a SQUID via an input coil. These coils are usually made of thin insulated superconducting (typically, Niobium) wire wound over some non-conducting cylindrical support, although in some instances they are integrated on a chip with a SQUID.

The SQUID and the coils must be kept superconducting. This is achieved by keeping them immersed in liquid helium at temperatures only a few degrees above absolute zero (about −460° F., or −269° C., or 4° K).

FIG. 1 illustrates an arrangement to measure the average projection of the magnetic field threading the detection coil along the coil's normal, B_{z}=Φ_{B}/A, where A is the area of the detection coil and z is the direction of the normal to the coil area. The two Josephson junctions in a superconducting SQUID loop are indicated by two crosses in FIG. 1. As can be seen, there is no direct electrical contact between the SQUID loop and the input coil: they are coupled inductively. This arrangement is called a magnetometer.

All SQUID instruments, such as biomagnetometers, are susceptible to commonplace external environmental magnetic background and magnetic interference (noise), such as magnetic field of the Earth and its fluctuations, as well as generally changing (time dependent) magnetic fields from electric machinery, power lines, trains, cars, etc. In biomagnetic applications, these interferences and any ancillary magnetic noise (that is ubiquitous within an industrial, urban or hospital environment) are typically contained via the use of magnetically shielded rooms that screen out these unwanted fields.

The least expensive shielded rooms cost about $300,000, whereas a good quality shielded room costs well over $1,000,000. Most hospitals are hard-pressed to dedicate precious space and funds for biomagentic applications that have not yet achieved widespread clinical utility. By virtue of their cost and size, the complexity associated with SQUID systems, and the need for shielded rooms, the introduction of SQUIDs into medical practice (especially in heart diagnostics) is slow.

While most desirable in applications, open-space, unshielded operation is difficult because of the extreme sensitivity of SQUID sensors. A number of technical measures must be taken in order to allow operation without magnetic shielding. These include filtering out of the unwanted frequencies, electronic noise suppression, and, most importantly, the use of well-balanced subtracting detection coils called gradiometers. Gradiometers are tools for efficient magnetic field measurement of nearby magnetic sources of interest in the presence of ambient magnetic field and magnetic noise.

A gradiometer is an arrangement of two or more axially positioned superconducting wire coils intercepting magnetic flux. FIGS. 2a and 2b collectively illustrate a first and second order gradiometer. In a first order gradiometer, there are two nominally identical coils, said coils wound in such a way as to cancel out the constant component of the field in the direction of the gradiometer axis. In the simplest implementation these are single turn (single loop) coils, as shown in FIG. 2a. There are three coils in a second order gradiometer, said coils containing 1-2-1 turns (loops) in the simplest implementation shown in FIG. 2b, said coils being wound in a way as to cancel the constant component of the field and the approximate first spatial derivative of the magnetic field in the direction of the gradiometer axis. (The words loops or turns are used interchangeably in what follows).

Similarly, one can wind a 3^{rd} order gradiometer, which would consist in the simplest implementation of four coils containing 1-2-2-1 loops, and so on, for even higher orders (see for example A. I. Braginski, H. J. Krause, and J. Vrba, in Handbook of Thin Film Devices, edited by M. H. Francombe, v. 3: Superconducting Film Devices, Chapter 6, p.149, Academic Press (2000), incorporated here as a reference).

Upon a division of the measured magnetic flux by the coil area A, the signals measured in these arrangements are:

For the 1^{st} order gradiometer in FIG. 2a: S₁=B_{z}(z₀)−B_{z}(z₀+l)

For the 2^{nd} order gradiometer in FIG. 2b: S₂=B_{z}(z₀)−2B_{z}(z₀+l)+B_{z}(z₀+2l),

where l is the distance between the coils called gradiometer base line, or base. The base is typically chosen to be approximately equal to half distance from the lower detection coil to the magnetic field source (e.g., the heart), in-order to optimize signal-to-noise. In gradiometers designed for heart measurements, l is typically chosen to be from 4 to 7 cm; most typically about 5 cm.

It should be noted that in the limit of l→0 the signals S₁ and S₂ are proportional to the first and second spatial derivatives of B with respect to z respectively, which is equivalent to considering distant sources removed from the gradiometer by distances much greater than l. Indeed, taking the ratio of S₁ to l and of S₂ to l² and further taking the limit l→0, it is found that:

$$\frac{ⅆ {B}_{z}}{ⅆ z} = lim ( \frac{Δ {B}_{z}}{Δ z} ) = lim \frac{[ {B}_{z} ( {z}_{0} ) - {B}_{z} ( {z}_{0} + l ) ]}{l} = lim \frac{{S}_{1}}{l} as l -> 0 ;$$

and

$$\begin{matrix}\begin{matrix}\frac{{ⅆ}^{2} {B}_{z}}{ⅆ {z}^{2}} = lim Δ [ ( \frac{Δ {B}_{z}}{Δ z} ) ] / Δ z \\ = lim \frac{[ {B}_{z} ( {z}_{0} ) - 2 {B}_{z} ( {z}_{0} + l ) + {B}_{z} ( {z}_{0} + 2 l ) ]}{{l}^{2}} \\ = lim \frac{{S}_{2}}{{l}^{2}}\end{matrix} \\ as l -> 0 ;\end{matrix}$$

Thus, for a finite l, these signals are approximately proportional to said derivatives with the base l as proportionality coefficient: in case of a 1^{st} order gradiometer, S₁≈l (dB_{z}/dz), and in case of a 2^{nd} order gradiometer, S₂≈l (d²B_{z}/dz²).

Thus, the first order gradiometer rejects constant field B_{z} from distant sources, as the derivative of a constant field is zero. The second order gradiometer rejects both constant B_{z} and constant (linear) slope dBz/dz from distant sources, measuring only deviations from the linear slope of B_{Z}(z). It should be noted that these statements are strictly true only for infinitely distant sources and only approximately true for distant sources. As to nearby sources at a distance comparable with l (i.e., for the source of interest, such as, for example, the human heart), gradiometers do not measure derivatives at all. In fact, since the strength of a signal B_{z} from such a nearby source is a fast falling function of distance z (for a dipole or nearly-dipole source, it decreases approximately as 1/z³), and because the base is chosen to be about ½ distance to the source, the 2^{nd} order gradiometer mostly measures B_{z}(z₀), since B_{z}(z₀+l) and B_{z}(z₀+2l) are considerably smaller than B_{z}(z₀). It can further be shown that the arrangement shown in FIG. 2b measures about 0.4 of the corresponding magnetometer signal (that is, arrangement of FIG. 1). This loss of a part of a signal (i.e. a decrease in sensitivity) is the price paid for being able to subtract the unwanted contribution from distant sources, as explained above. Thus, a 2^{nd} order gradiometer is acting almost as a magnetometer for nearby sources, while subtracting B_{z} and dBz/dz for distant sources.

It should be also recalled that, by nature of superconductivity, gradiometer coils react to magnetic flux rather than to magnetic field. One should not forget that in the formulas above the flux was divided by the coil area A, with the assumption that this area is identical for different coils. As will be discussed in detail below, generally this is not so, and hence coils area differences can create gradiometer imbalances.

A Practical Gradiometer

A practical gradiometer is an axial construction made with superconducting Niobium (Nb) wire wound around an insulating cylindrical support about 20 mm in diameter. Such a gradiometer is effective in subtracting magnetic flux, its first derivative, etc. (depending on its construction, or its order) via appositely wound coils, only to the extent that such coils are equal in area and their planes are parallel to each other. An extent to which two nominally identical, appositely wound coils perform this function is called the mechanical gradiometer balance. For example, in the case where a constant magnetic field is threading the gradiometer, and the gradiometer rejects 999 parts of that field out of 1000, the mechanical balance is 1:1000, or 10⁻³. The remaining 1 part in a 1000 (called common mode response) comes from imperfect area equality and/or imperfect plane parallelism of the gradiometer coils.

Certain ways of achieving and improving this balance have been implemented in the prior art. One way to improve the area equality and parallelism is to provide precise guiding grooves for the superconducting wire on a cylindrical support. This has been done with the use of a lathe to cut helical v-grooves into the cylinder support sides, essentially using a common lathe technique of screw thread cutting. The precision of such cutting is primarily determined by a large, precisely made master screw in the lathe. The precise period of that lathe master screw is reduced by gears and eventually transferred to the cylinder support. This technique has been beneficially applied to producing high-balance gradiometers for a number of years, in particular in systems sold to various customers by Cryogenic Electronic Systems Corporations®.

It should be noted that the above-described method of creating a slightly slanted, helical groove geometry does not adversely affect the gradiometer balance as long as the two grooves are slanted at the same angle. However, unless the slant is corrected for, it creates a small error in measuring B_{z}.

Furthermore, in order to use the screw-threading technique, as a minimum, the material of the cylinder must allow machining on a lathe. Additionally, the material must also be non-magnetic and insulating to prevent magnetic and RF (eddy-current) interference with the SQUID. Moreover, it is preferable that the material has a coefficient of thermal expansion matching that of the Niobium (Nb) wire, or slightly smaller in order to keep wire at a tension when the gradiometer is cooled down. In prior art systems, various machinable ceramics are used, including the well-known machinable ceramics called maicor.

One problem associated with maicor, however, is in that it is an inherently grainy material. The graininess associated with maicor is due to the fact that it is prepared by high-temperature baking from ceramic powder. These grains and agglomerates of grains, several micron in size, prevent one from achieving the highly polished surface in the machined groove, which makes the thread precise. Secondly, large-scale inhomogeneous areas in the maicor appear in various regions, wherein the inhomogeneous areas probably originate from non-uniformity of the ceramic baking process. All of this contributes to the machined diameter variation (dR) of as much as 10-20 microns on a 20 mm diameter (R=10 mm) support.

It is easy to estimate the degree of imbalance resulting from such diameter variations. As was stated earlier, gradiometer coils react to magnetic flux Φ_{B}=B_{z}A, and therefore imbalance of area A leads to imbalance in flux. Since the variation of the radius dR is much smaller than the radius R, a relative error dA in the area A, dA/A, is equal with good precision to

$$dA / A = \frac{d}{π {R}^{2}} ( π {R}^{2} ) = \frac{2 dR}{R}$$

For dR=10 μm and R=10 mm=10,000 μm:

$$dA / A = \frac{2 dR}{R} = \frac{2 \times 10 µm}{10 \text{,} 000 µm} = 2 \times {10}^{- 3}$$

It should be noted that there are various other sources of mechanical imbalance. But, the principal problem is in keeping the wires at a tension during winding, since the slack greatly contributes towards gradiometer imbalance. With all the other factors contributing, a mechanical balance of about 10⁻² has been achieved in the best of prior art systems.

One way of improving on this mechanical balance is to place small superconducting trim tabs in the vicinity of a gradiometer. Thus, the gradiometer is placed inside large Helmholtz coils capable of producing uniform magnetic field, with uniformity to about a factor of 10⁻⁵ −10⁻⁶. Using constant field, the tabs are mechanically adjusted to minimize common mode response. However, this technique has several disadvantages associated with it. For example, the method is difficult because it requires two or more rigid sticks connected to the tabs in order to adjust their position. The adjustment thus achieved produces undesirable field distortion, and further the achieved balance can change (drift away) with time. Additionally, it is not practical for a large number of channels.

In order to electrically connect the different gradiometer coils and loops, one needs to run a pair of wires vertically down the side of the cylindrical support structure. This segment of the continuous superconducting wire is always being twisted (a twisted pair) in order to eliminate or minimize the parasitic flux pickup through the thin gap between such two wires. In a twisted pair the flux through each pair of adjacent mini-loops has different sign, and the total parasitic flux averages to near zero.

Described below is a prior art reference describing noiseless magnetic field measurement, but it should be noted that prior art systems such as this fail to mention a method for achieving higher mechanical balance via an efficient way for winding the superconducting wire (of the gradiometer). Furthermore, the prior art fails to optimize the use of magnetometers in conjunction with gradiometer to achieve higher balance.

The U.S. Patent to Mallick (5,187,436) provides for a system and method for noiseless measurement of a biomagnetic field using magnetic field magnitude and gradient measurement at a reference point together with mathematical extrapolation techniques to provide an effective infinite order gradiometer. But, there is no mention of an efficient way for winding the superconducting wire in the support for achieving better mechanical balance.

Furthermore, the prior art systems fail to address the following issues of importance with regard to the performance and cost of gradiometers: a) the prior art fails to identify a suitable material for the cylindrical support, b) the prior art fails to identify a practical way of winding superconducting wire on the support that allows reliably achieving stable mechanical balance of up to 10⁻³, and c) the prior art fails to relate this mechanical balance with the design of the electronic balancing part (reference channels).

Whatever the precise merits, features and advantages of the above described prior art systems, none of them achieve or fulfills the purposes of the present invention.

### SUMMARY OF THE INVENTION

The present invention provides for the construction of a high balance gradiometer with the mechanical balance ranging from about 4×10⁻⁴ to about 10⁻³. This high balance is achieved via three ways: 1) the use of Pyrex® as the gradiometer support material, 2) an improved method for winding superconducting wire loops with equal loop areas, 3) minimal number of turns for each gradiometer used. The mechanical balance is further improved by an optimized electronic implementation of the reference channels.

Pyrex is the choice of gradiometer support material since it has a coefficient of thermal expansion similar to that of Niobium and therefore helps in avoiding the formation of slack in the Niobium wires upon cooling from room temperature to the operational temperature of the system. Furthermore, Pyrex being an amorphous glass provides for a precise and smooth finish, thereby providing better gradiometer balance.

The improved method for winding loops with equal area is done via the use of fast setting glue such as cyanoacrylate glue, which prevents the formation of slack in the Niobium wire. The present invention provides for an efficient way to fix in place (without slack) the Niobium wire of the gradiometer loops and the vertical twisted wire pair of the gradiometer.

Additionally, the choice of number of loops in the gradiometers is restricted to a minimum to maintain gradiometer sensitivity.

Lastly, optimized SQUID magnetometers are provided to measure magnetic fields in the X, Y, and Z directions (reference channels). These measured fields are then fed into the software to compensate for the imbalances in the X, Y, and Z directions. The said optimization consists of providing such X, Y, Z SQUID loop areas as to match the existing mechanical imbalance in the measuring channel gradiometers.

### BRIEF DESCRIPTION OF THE DRAWINGS

FIG. 1 illustrates an arrangement to measure the average projection of the magnetic field threading the detection coil along the coil's normal (SQUID magnetometer).

FIGS. 2a and 2b illustrate a first and second order gradiometer respectively.

FIGS. 3a and 3b collectively illustrates the wire fixing technique of the present invention.

FIG. 4 illustrates the present invention's method for the construction of a gradiometer with high balance.

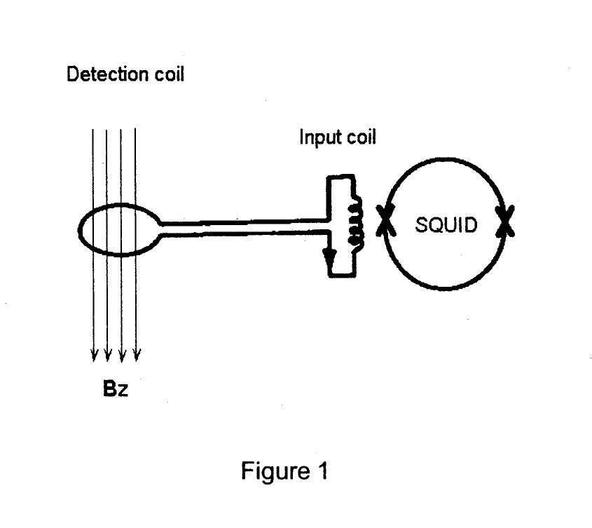

### DESCRIPTION OF THE PREFERRED EMBODIMENTS

While this invention is illustrated and described in a preferred embodiment, the invention may be produced in many different configurations, forms and materials. There is depicted in the drawings, and will herein be described in detail, a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the present invention.

Use of Pyrex® Glass as Gradiometer Support

Pyrex is found to have exceptional characteristics as a gradiometer support material: 1) it is non-magnetic and insulating, and 2) it has a coefficient of thermal expansion α=(9-10)×10⁻⁶K⁻¹, which is similar to the Nb coefficient, α=7×10⁻⁶K⁻¹ (both values are quoted at room temperature). The close match of thermal expansion is found to be beneficial, since the Nb wire does not acquire significant slack as the gradiometer cools down from room temperature to 4K. Furthermore, the tension in the wire helps to achieve high balance, however, it is not so high as to break the wire. Additionally, Pyrex is an amorphous glass without any internal structure down to a molecular level. Because of that, and utilizing water cooling of the lathe, Pyrex can be machined to a high precision and smooth finish. The deviations of loop diameters are found to be within (2-4) μm, compared to about 10 μm -20 μm in case of a maicor. Additionally, with good modern cutting equipment one can achieve approximately 1 μm precision using glasses as opposed to ceramics. The (2-4) μm deviation by itself allows a balance of about:

$$dA / A = \frac{2 dR}{R} = \frac{2 \cdot ( 2 - 4 ) µm}{10 \text{,} 000 µm} = ( 4 - 8 ) \times {10}^{- 4}$$

Finally, Pyrex is cheap compared to machinable ceramics that were used previously (such as maicor); the latter cost about $200 per gradiometer support versus about $5 for a Pyrex support. This is an important consideration in a multichannel system.

It should be noted that although the specific example of Pyrex is used to illustrate the preferred embodiment of the present invention, one skilled in the art can envision other gradiometer support materials without departing from the scope of the present invention. For example, one skilled in the art will recognize the use of non-magnetic glasses with coefficients of thermal expansion similar to that of Niobium or to other superconducting wire material (e.g. glasses with coefficient of thermal expansion smaller than approximately 10⁻⁵ K⁻¹).

A Way of Winding Superconducting Wire Loops With Equal Loop Areas

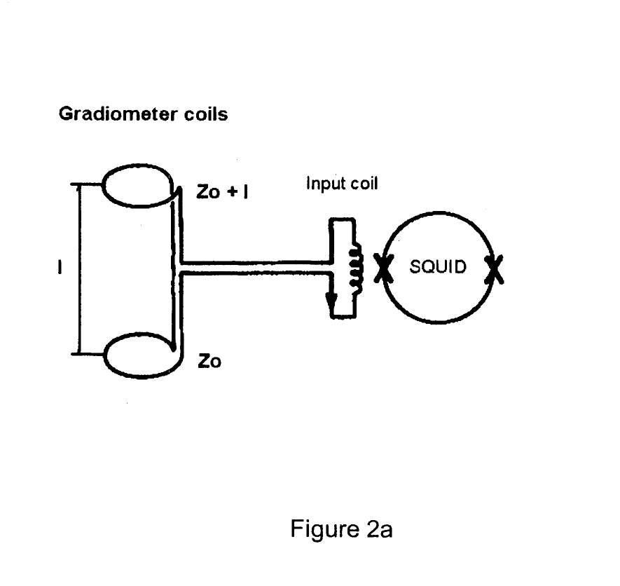

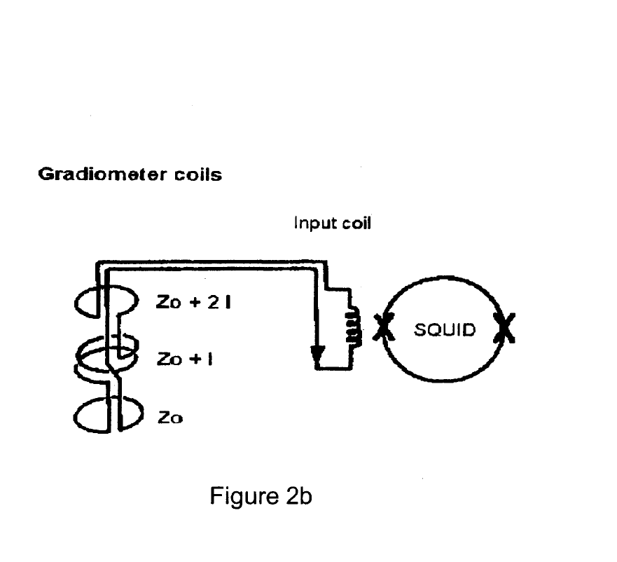

While providing a method for making high quality gradiometers of any order, the specification mainly concentrates on the 2^{nd} order gradiometer schematically shown in FIG. 2b, since it is the most commonly used gradiometer in biomagnetic measurements, in particular, heart measurements.

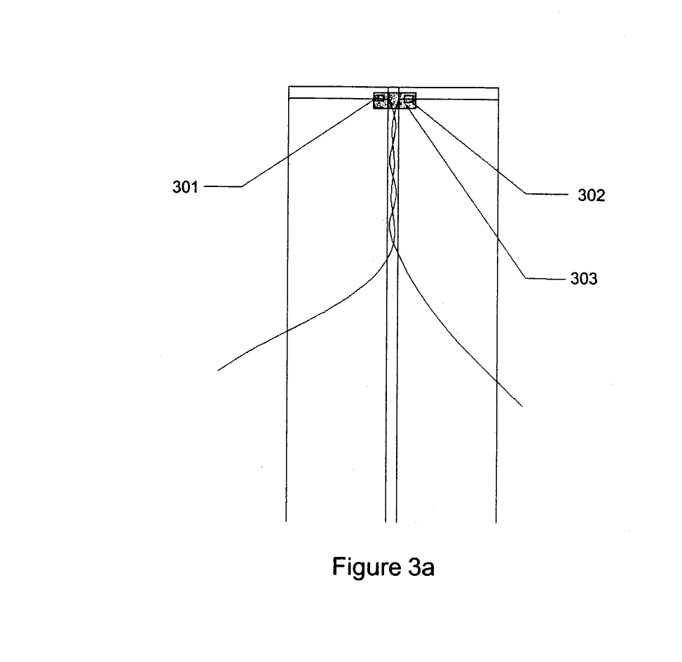

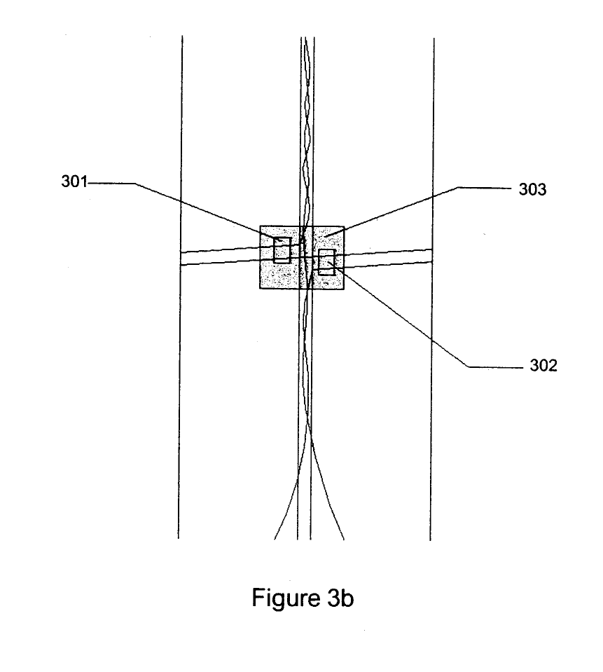

The V-shaped grooves (60 degrees) for gradiometer wires are machined with high precision on a Pyrex glass tube. The circular near-horizontal grooves are connected by a straight vertical groove intended for the twisted pair connection between the horizontal loops. The depth of the circular grooves is chosen to be just sufficient for the wire to sink in (e.g., Nb wire diameter was 70 μm); the depth of the vertical groove is 1.5 times greater in order to house the twisted pair of wires. An important aspect of the present invention involves winding the superconducting Nb wire in these grooves under tension. This provides for a condition in which there is no slack in the wire, thereby achieving a high balance. A challenging aspect in this procedure is in going from the horizontal loop into a vertically-directed twisted pair. It is very hard to maintain tension at that stage; this lack of tension results in a slack, and the 1:1000 balance is lost. This problem is alleviated by using a fast-setting cyanoacrylate glue, which solidifies in 5-15 seconds, depending on the type used. Moreover, cyanoacrylate glue has excellent adhesion to Pyrex glass. This procedure is illustrated in FIGS. 3a and 3b.

As shown in FIG. 3a, the wire fixing technique uses fast-setting glue in winding the outer loop and the vertical twisted pair. In this technique, the wire is fixed by a small drop of the glue at point 301, near the edge of the vertical groove. The glue is allowed to solidify, which takes only a few seconds, before proceeding with the wire winding. This fixing point allows winding the loop under tension. Once the loop is finished, the other side of it is similarly fixed at a point 302, near the other side of the vertical groove. Upon this fixation, the wire now can be placed into the vertical groove under tension, forming the twisted pair. As soon as a couple of twists are completed, the whole region is covered with the larger amount of glue shown as shaded region 303. This completely fixes the area between the loop and the vertical groove.

FIG. 3b illustrates the winding technique of the inner double loop coil and connections to the vertical twisted pairs. In this case, the process starts by going from a vertical direction into the double loop. At this point one has to first provide tension for the vertical twisted pair. This is done without a use of glue, by either utilizing a fact that wires at this point turn on a 90 degree angle, and using friction at the V-groove bend, or by employing a mechanical clamp (not shown on FIG. 3b). Once the wire faces in the horizontal direction, it is again fixed with glue drop 301; next, the double loop is completed under tension and fixed with drop 302. Next, the twisted pair is started in the downward vertical direction and the whole area is covered with glue 303 (shaded area in FIG. 3b).

It should be noted that in the preferred embodiment, all grooves are subsequently filled with the glue, in order to provide stability to the mechanical gradiometer balance and to protect the wires during thermal cycling of the apparatus.

The Choice of the Number of Loops

In the prior art, gradiometers were often wound using more than a single turn in each coil; for example, two or more turns are often used on each coil level (i.e., the 2^{nd} order gradiometer may be wound with 2-4-2 turns rather than in a minimum configuration of 1-2-1 turns as in FIG. 2b). This was done with an aim to increase the flux threading each coil in proportion to the number of turns.

It was recognized in the prior art that magnetic field resolution of a SQUID is independent of the number of turns in a pickup coil. However, it was not explicitly stated that increasing the number of turns is actually detrimental to gradiometer operation. Indeed, increasing the number of turns over the minimum will increase the gradiometer coil inductance faster than the captured flux. As is well-known, the inductance of a long solenoid is proportional to the number of turns squared, N², while for a fixed B field the flux threading the solenoid is proportional only to N. In a configuration with a small number of turns (short solenoid), the power will be smaller than 2, but higher than 1. Increasing inductance over the flux is counterproductive: this will decrease the current in the coil, thus reducing gradiometer sensitivity to the external field.

Hence, the preferred embodiment contains the minimal number of turns for each gradiometer type, for example, 1-2-1 for a 2^{nd} order gradiometer. It is also easier to achieve wire tension and higher balance in this case.

Considerations for Electronic Noise Suppression System

In addition to achieving a mechanical balance of about 10⁻³, an electronic means of improving this balance is provided. This so-called Electronic Noise Suppression System, or ENSS, consists of several low-sensitivity magnetometers (reference channels) placed among gradiometer channels (signal channels), said reference channels having their associated electronics. Such ENSS were described in prior art (for example, see A. N. Matlashov et. al. in Advances in Biomagnetism, Eds. S. J. Williamson, M. Hoke, G. Stroink, and M. Kotani, Plenum Press, New York and London, pp. 725-728, (1989), incorporated here as a refence). These magnetometers are SQUIDs with their own loops intercepting the magnetic flux (i.e., SQUIDs without detection coils). They are designed to have a sensitivity low enough to function properly as magnetometers. They are positioned with SQUID loop areas facing in three orthogonal directions, X, Y and Z (practically, SQUIDs are placed on three orthogonal faces of a cube). They are also called vector magnetometers.

Suppose that in the uniform calibrating field of a Helmholtz coil gradiometer shows its imperfect balance of, say, 1 part in N_{X}, one part in N_{Y} and one part in N_{Z} in X, Y, Z-directions (i.e., with uniform magnetic field pointing in X, Y, Z directions) respectively), where N_{X}, N_{Y}, N_{Z} are numbers of the order of 1000 in the present technology. If the magnetic field, for example, doubles in magnitude, so does the corresponding common mode signal resulting from gradiometer imbalance. At the same time XYZ magnetometers are measuring the fields in these directions. Their signals can be inverted, properly scaled, and electrically fed into the output of signal channels to compensate for these remaining imbalances. If a given signal, for example from X, is smaller than the corresponding gradiometer imbalance signal in X direction, it is amplified. If it is larger, it is reduced. One finds appropriate coefficients that take care of the gradiometer imbalance in this way. These coefficients are greater than unity in the case when amplification is required, and less than unity if SQUID signal is too large.

However, it should be noted that amplification of the signal from X-SQUID simultaneously amplifies noise, and thus such amplification is undesirable. On the other hand, having X-SQUID that is too sensitive for this task is also undesirable, since this will decrease its dynamic range. Hence the conclusion is that in the preferred embodiment X-, Y-, Z-SQUIDs should have their loop areas chosen so as to correspond as closely as possible to the expected maximum mechanical gradiometer imbalances in these directions. For example, if it is known that a specific fabrication technology produces a maximum mechanical imbalance of 2×10⁻³ in X direction, the X-magnetometer SQUID is constructed to compensate for this imbalance signal with coefficient close to unity. In other words, when a signal measured by said X-SQUID is electronically inverted, it will roughly cancel the imbalance signal.

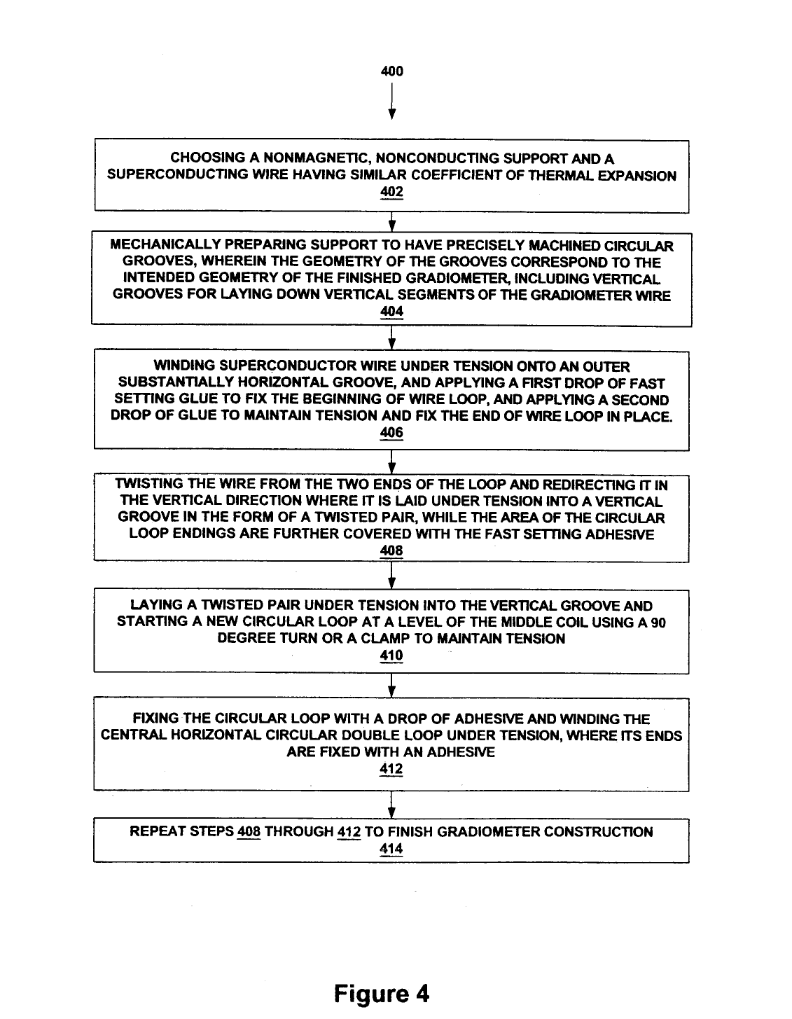

FIG. 4 summarizes method 400 of the present invention, illustrated in the steps taken in winding of the second order gradiometer. First, a nonmagnetic, nonconducting support and a superconducting wire are chosen so that they have a substantially equal coefficient of thermal expansion 402; next said support is mechanically prepared to have precisely machined circular grooves, the geometry of said grooves corresponding to the intended geometry of the finished gradiometer, including also vertical grooves for laying down vertical segments of the gradiometer wire 404; next, continuous superconducting wire is wound under tension onto an outer (either the uppermost or the lowermost) substantially horizontal circular groove, with the first drop of a fast-setting glue (adhesive) applied to fix the beginning of said wire loop and to help maintain said tension, and a second similar drop applied to fix the end of said wire loop in place, 406; next, the wire from said two ends of the loop is twisted together and redirected in the vertical direction and laid under tension into a vertical groove, in a form of a twisted wire pair, while the area of the circular loop endings is further covered with said fast-setting adhesive, 408; next, said twisted pair is laid under tension into the vertical grove, and at the level of the middle coil a new circular loop is started, using a 90 degree turn or a clamp to maintain tension, 410; next, as soon as the circular loop is started, it is fixed with the drop of adhesive, and the central horizontal circular double loop is wound under tension, its end again fixed with adhesive 412; next, the steps 408 and 410 are repeated, to finish gradiometer construction, 414.

Lastly, at least three vector magnetometers are prepared with SQUID loop areas corresponding to expected area imbalances of the gradiometer coils in said directions. The normals to their loop areas are facing in the X, Y, and Z directions. The signals from these vector magnetometers are inverted and fed into the outputs of measuring channels to compensate remaining gradiometer imbalances in each of these axes, 416.

### Conclusion

A system and method has been shown in the above embodiments for the effective implementation of a high balance gradiometer. While various preferred embodiments have been shown and described, it will be understood that there is no intent to limit the invention by such disclosure, but rather, it is intended to cover all modifications and alternate constructions falling within the spirit and scope of the invention, as defined in the appended claims. For example, the present invention should not be limited by type of support material, type of glue, the order of the gradiometer, or specific electronic hardware.

1. A gradiometer comprising:
a non-magnetic insulating gradiometer support having a first coefficient of thermal expansion, α₁, said support further comprising near horizontal near circular grooves and connecting straight near vertical grooves, and
a continuous superconducting wire retained inside said grooves with two or more gradiometer coil loops connected via one or more vertical twisted pair of wires, said loops of nearly equal area and said wire having a second coefficient of thermal expansion, α₂, said α₂ either equal to, or substantially equal to, α₁, and said gradiometer coil loops wound under tension in said near horizontal grooves and said vertical twisted pair of wires wound under tension in said vertical grooves, said wire being wound under tension using fast-setting glue for fixing the 90 degree turns in the wire direction, and being held in place on said gradiometer support using a glue.

2. A gradiometer as per claim 1, wherein said gradiometer is used in conjunction with additional directional X, Y, Z SQUID magnetometers, said magnetometers having their loop areas chosen as to approximately correspond to the mechanical imbalances characteristic of the said gradiometer imbalances in said corresponding directions.

3. A gradiometer as per claim 1, wherein said gradiometer support material is made of a non-magnetic insulating glass.

4. A gradiometer as per claim 3, wherein said non-magnetic insulating glass is Pyrex.

5. A gradiometer as per claim 1, wherein the superconducting wire is a Niobium or a Niobium alloy wire.

6. A gradiometer as per claim 1, wherein said glue is cyanoacrylate glue.

7. A gradiometer as per claim 1, wherein the depth of said vertical groove is greater than said near horizontal grooves.

8. A gradiometer as per claim 7, wherein ratio of said depth of said near vertical groove to said horizontal groove is approximately 1.5.

9. A gradiometer as per claim 1, wherein said near horizontal grooves are V-shaped.

10. A gradiometer as per claim 1, wherein said constructed gradiometer is any of the following: a first order, a second order, or a third order gradiometer with a minimal number of loops.

11. A method for constructing a gradiometer with high balance, said method comprising the steps of:
(i) winding a continuous wire onto two or more substantially horizontal and vertical grooves on a non-magnetic non-conducting support, both said wire and support having either equal, or substantially equal, coefficients of thermal expansion, said wire wound under tension on said substantially horizontal grooves forming gradiometer coils and said wire twisted and held in said vertical grooves forming a twisted pair, said twisted pair connecting said gradiometer coils;
(ii) applying a glue in the process of winding of said wire to hold said wire under tension in said substantially horizontal and vertical grooves.

12. A method for constructing a gradiometer with high balance, as per claim 11, wherein said constructed gradiometer has a final mechanical balance of about 10⁻³.

13. A method for constructing a gradiometer with high balance, as per claim 11, wherein said method further comprises the step of preparing at least three SQUID magnetometers measuring magnetic flux directly with their SQUID loop areas, having said SQUID loop areas substantially equal said gradiometer coil area imbalances, and aligning said three magnetometers in the X, Y, and Z directions and measuring magnetic fields in said axes and compensating remaining gradiometer's mechanical imbalances in each of said axes by inverting corresponding magnetometer signals and feeding them into said gradiometer output signals.

14. A method for constructing a gradiometer with high balance, as per claim 13, wherein said wire is made of Niobium or Niobium alloy.

15. A method for constructing a gradiometer with high balance, as per claim 14, wherein said non-magnetic non-conducting support is made of Pyrex.

16. A method for constructing a gradiometer with high balance, as per claim 11, wherein said glue is cyanoacrylate glue.

17. A method for constructing a gradiometer with high balance, as per claim 11, wherein said gradiometer is either a first order, or a second order, or a third order gradiometer with a minimal number or coils.

18. A gradiometer support system operatively connected to one or more SQUID channels used in measuring magnetic fields associated with a heart, said measurement based upon the amount of current induced in one or more gradiometer coils in said support, said support system further comprising
a non-magnetic non-conducting gradiometer support having a first coefficient of thermal expansion, α₁, said support further comprising near horizontal grooves and vertical grooves, and
a continuous wire with two or more gradiometer coil loops connected via one or more vertical twisted pairs, said loops of equal area and said wire having a second coefficient of thermal expansion, α₂, said α₂ either equal to, or substantially equal to, α₁, and said gradiometer coil loops residing under tension in said near horizontal grooves and said vertical twisted pairs residing under tension in said vertical grooves, said wire being wound under tension and held in place on said gradiometer support using a glue.

19. A cardiac device for measuring magnetic fields associated with a heart, as per claim 18, wherein said cardiac device further comprises at least three optimized SQUID magnetometers aligned in the X, Y, and Z axes measuring magnetic fields along said axes, said optimization accomplished via choosing loop areas associated with said magnetometers to be substantially equal to loop area imbalances expected in said gradiometer coil loops.

20. A cardiac device for measuring magnetic fields associated with a heart, as per claim 18, wherein distance between said gradiometer coil loops is chosen to be half the distance between a lowest of said gradiometer coil loops and said heart.

21. A cardiac device for measuring magnetic fields associated with a heart, as per claim 18, wherein said non-magnetic non-conducting gradiometer support is made of Pyrex.

22. A cardiac device for measuring magnetic fields associated with a heart, as per claim 18, wherein said wire is made of Niobium or Niobium alloy.

23. A cardiac device for measuring magnetic fields associated with a heart, said system comprising
a gradiometer support made of Pyrex comprising near horizontal grooves and vertical grooves;
a continuous Niobium or Niobium alloy wire with two or more gradiometer coil loops connected via a vertical twisted pair, said loops of equal area and said Niobium wire having a coefficient of thermal expansion either equal to, or substantially equal to, that of Pyrex, and said gradiometer coil loops residing under tension in said near horizontal grooves and said vertical twisted pair being wound and residing under tension in said vertical grooves, said Niobium wire being wound under tension and held in place on said gradiometer support using an cyanoacrylate glue, and
at least three optimized SQUID magnetometers aligned in the X, Y, and Z axes measuring magnetic fields along said axes, said magnetometer outputs, when inverted, essentially canceling gradiometer imbalances in said X, Y, Z directions.

24. A cardiac device for measuring magnetic fields associated with a heart, said system comprising:
a gradiometer support made of Pyrex comprising near horizontal grooves and vertical grooves;
a continuous Niobium or Niobium alloy wire with two or more gradiometer coil loops connected via vertical twisted pairs, said loops of equal area and said Niobium or Niobium alloy wire having a coefficient of thermal expansion either equal to, or substantially equal to, that of Pyrex, and said gradiometer coil loops residing under tension in said near horizontal grooves and said vertical twisted pairs being wound and residing under tension in said vertical grooves, said Niobium or Niobium alloy wire held in place on said gradiometer support using an cyanoacrylate glue, and
at least three optimized magnetometers aligned in the X, Y, and Z axes measuring magnetic fields along said axes and compensating gradiometer's mechanical imbalances in each of said axes with coefficients close to unity.
